(19) United States
(12) Patent Application Publication
(10) Pub. No.: US 2026/0026404 A1
(43) Pub. Date: Jan. 22, 2026

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Junghoon KANG, Suwon-si (KR); Hangi JUNG, Suwon-si (KR); Hyunsoo CHUNG, Suwon-si (KR)

(73) Assignee: SAMSUNG ELECTRONICS CO., LTD., Suwon-si (KR)

(21) Appl. No.: 19/051,956

(22) Filed: Feb. 12, 2025

(30) Foreign Application Priority Data
Jul. 17, 2024 (KR) 10-2024-0094611

(51) Int. Cl. H01L 25/16; H01L 23/00; H01L 23/31; H01L 23/48; H01L 23/538; H01L 25/00

(52) U.S. Cl. CPC H01L 25/16; H01L 23/3135; H01L 23/481; H01L 25/50; H01L 23/538; H01L 24/16; H01L 24/32; H01L 24/73; H01L 24/81; H01L 24/83; H01L 24/92; H01L 2224/16148; H01L 2224/32145; H01L 2224/73204; H01L 2224/81203; H01L 2224/83203; H01L 2224/9211; H01L 2225/06513; H01L 2225/06541; H01L 2225/06565

(57) ABSTRACT

Provided is a semiconductor package including a plurality of first semiconductor chips respectively including a first semiconductor substrate and a plurality of first through electrodes penetrating the first semiconductor substrate, a second semiconductor chip on the plurality of first semiconductor chips, the second semiconductor chip including a second semiconductor substrate and a plurality of second through electrodes penetrating the second semiconductor substrate, a third semiconductor chip on the second semiconductor chip, the third semiconductor chip including a third semiconductor substrate and a plurality of third through electrodes penetrating the third semiconductor substrate, and a first encapsulation material on the plurality of first semiconductor chips, a planar shape of the second semiconductor chip is greater than a planar shape of each first semiconductor chip of the plurality of first semiconductor chips, and a planar shape of the third semiconductor chip is greater than the planar shape of the second semiconductor chip.

### CROSS-REFERENCE TO RELATED APPLICATION

This application claims priority to Korean Patent Application No. 10-2024-0094611, filed on Jul. 17, 2024, in the Korean Intellectual Property Office, the disclosure of which is incorporated by reference herein in its entirety.

### BACKGROUND

Embodiments of the present disclosure relate to a semiconductor package and a method of manufacturing the same, and more particularly, to a semiconductor package including a plurality of semiconductor chips that are stacked and a method of manufacturing the same.

Along with the rapid development of the electronics industry and demands of users, electronic devices have been gradually miniaturized and the weight has been reduced, and accordingly, the high integration and large capacity of a semiconductor device that is a core component of an electronic device have been demanded, but the high integration of a semiconductor device has reached the limit. Accordingly, to achieve a large capacity, a semiconductor package including a plurality of semiconductor chips has been developed. Along with the demand of the large capacity of a semiconductor device, a semiconductor package including a plurality of semiconductor chips that are stacked has been developed.

Because there are various demands according to different industry fields using a semiconductor package, manufacturing semiconductor packages in response to the various demands is needed. When a semiconductor package including a plurality of semiconductor chips that are stacked is manufactured, manufacturing semiconductor packages in response to various demands according to usages is needed. Recently, manufacturing a semiconductor package including stacked memory chips so as to meet a particular demand of a usage is also needed.

### SUMMARY

One or more embodiments provide a semiconductor package including a plurality of semiconductor chips that are stacked while more efficiently manufacturing a customized memory semiconductor package that satisfies a particular requirement of a consumer.

According to an aspect of one or more embodiments, there is provided a semiconductor package including a plurality of first semiconductor chips respectively including a first semiconductor substrate and a plurality of first through electrodes penetrating the first semiconductor substrate, a second semiconductor chip on the plurality of first semiconductor chips, the second semiconductor chip including a second semiconductor substrate and a plurality of second through electrodes penetrating the second semiconductor substrate, a third semiconductor chip on the second semiconductor chip, the third semiconductor chip including a third semiconductor substrate and a plurality of third through electrodes penetrating the third semiconductor substrate, and a first encapsulation material on the plurality of first semiconductor chips, wherein a planar shape of the second semiconductor chip is greater than a planar shape of each first semiconductor chip of the plurality of first semiconductor chips, and a planar shape of the third semiconductor chip is greater than the planar shape of the second semiconductor chip.

According to an aspect of one or more embodiments, there is provided a semiconductor package including a primary semiconductor package including a plurality of first semiconductor chips respectively including a first semiconductor substrate and a plurality of first through electrodes penetrating the first semiconductor substrate, a second semiconductor chip on the plurality of first semiconductor chips, the second semiconductor chip including a second semiconductor substrate and a plurality of second through electrodes penetrating the second semiconductor substrate, an uppermost semiconductor chip on the plurality of first semiconductor chips, and a first encapsulation material on the plurality of first semiconductor, a third semiconductor chip on the primary semiconductor package, the third semiconductor chip including a third semiconductor substrate and a plurality of third through electrodes penetrating the third semiconductor substrate, and a second encapsulation material on the third semiconductor chip and the primary semiconductor package, wherein a planar shape of the second semiconductor chip is greater than a planar shape of each first semiconductor chip of the plurality of first semiconductor chips, a planar shape of the third semiconductor chip is greater than the planar shape of the second semiconductor chip, and wherein side surfaces of the first encapsulation material and side surfaces of the second semiconductor chip are aligned in a vertical direction, side surfaces of the third semiconductor chip and side surfaces of the second encapsulation material are aligned in the vertical direction, and an upper surface of the first encapsulation material is aligned with an upper surface of the second encapsulation material in a horizontal direction.

According to still another aspect of one or more embodiments, there is provided a method of manufacturing a semiconductor package, the method including forming a plurality of second semiconductor chips on a first wafer, stacking a plurality of first semiconductor chips on each second semiconductor chip of the plurality of second semiconductor chips on the first wafer, forming a first encapsulation material on the plurality of first semiconductor chips on the first wafer, dividing the first wafer, on which the plurality of first semiconductor chips are stacked, into a plurality of primary semiconductor packages that are spaced apart from each other, mounting the primary semiconductor packages on a third semiconductor chip, and forming a second encapsulation material on the primary semiconductor packages on the third semiconductor chip, wherein each first semiconductor chip of the plurality of first semiconductor chips, the second semiconductor chips, and the third semiconductor chip includes a plurality of first through electrodes, a plurality of second through electrodes, and a plurality of third through electrodes, respectively.

### BRIEF DESCRIPTION OF DRAWINGS

Embodiments will be more clearly understood from the following detailed description taken in conjunction with the accompanying drawings in which:

FIG. 1 is a cross-sectional view illustrating a semiconductor package according to one or more embodiments:

FIG. 2 is a cross-sectional view illustrating a semiconductor package according to one or more embodiments:

FIG. 3 is a cross-sectional view illustrating a semiconductor package including an interposer according to one or more embodiments:

FIG. 4 is a cross-sectional view illustrating a semiconductor package including an interposer according to one or more embodiments:

FIG. 5 is a cross-sectional view illustrating a semiconductor package including an interposer according to one or more embodiments:

FIGS. 6A, 6B, 6C, 6D, 6E, and 6F are cross-sectional views sequentially illustrating a method of manufacturing a semiconductor package, according to one or more embodiments: and

FIGS. 7A and 7B are cross-sectional views sequentially illustrating a method of manufacturing a semiconductor package, according to one or more embodiments.

### DETAILED DESCRIPTION

Hereinafter, one or more embodiments are described in detail with reference to the accompanying drawings.

In the specification, a first direction indicates the X direction, a second direction indicates the Y direction, and the first direction may be perpendicular to the second direction. A third direction indicates the Z direction, and the third direction may be perpendicular to each of the first direction and the second direction. A horizontal surface or a plane indicates an X-Y plane. The upper surface of a particular object indicates one surface of the particular object in the positive third direction, and the lower surface of the particular object indicates one surface of the particular object in the negative third direction.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

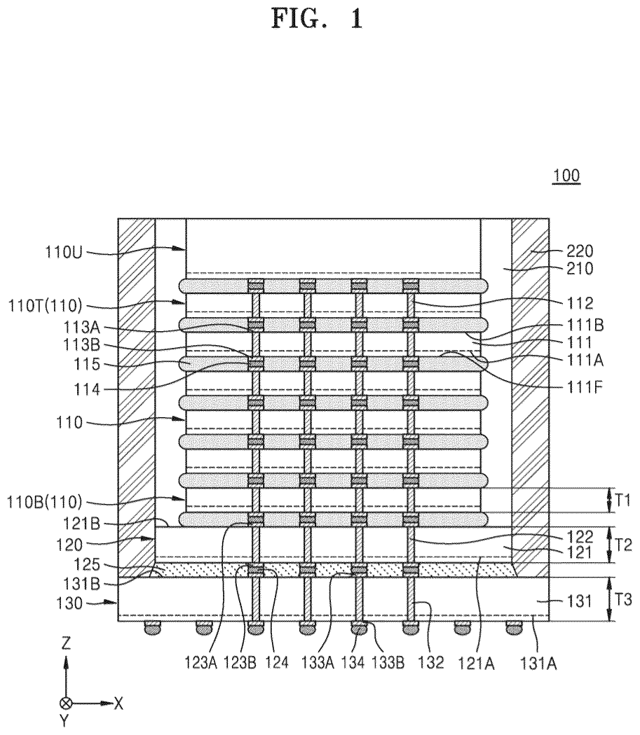

FIG. 1 is a cross-sectional view illustrating a semiconductor package 100 according to one or more embodiments.

Referring to FIG. 1, the semiconductor package 100 may include a first semiconductor chip 110, an uppermost semiconductor chip 110U, a second semiconductor chip 120, a third semiconductor chip 130, a first encapsulation material 210, and a second encapsulation material 220.

The first semiconductor chip 110 may be on the second semiconductor chip 120. Although FIG. 1 shows that the semiconductor package 100 includes eight semiconductor chips, e.g., six first semiconductor chips 110, the uppermost semiconductor chip 110U, and the second semiconductor chip 120, and one third semiconductor chip 130, the semiconductor package 100 is not limited thereto.

The semiconductor package 100 may include two or more first semiconductor chips 110. In one or more embodiments, the semiconductor package 100 may include a multiple of two first semiconductor chips 110. A plurality of first semiconductor chips 110 may be sequentially stacked on the second semiconductor chip 120. A first semiconductor chip 110 at the bottom among the plurality of first semiconductor chips 110 may be referred to as a bottom first semiconductor chip 110B, and a first semiconductor chip 110 at the top among the plurality of first semiconductor chips 110 may be referred to as a top first semiconductor chip 110T.

For example, the semiconductor package 100 may include four or more semiconductor chips including the first semiconductor chip 110, the uppermost semiconductor chip 110U, and the second semiconductor chip 120. For example, the semiconductor package 100 may include four semiconductor chips including two first semiconductor chips 110, the uppermost semiconductor chip 110U, and the second semiconductor chip 120 and include the third semiconductor chip 130. However, embodiments are not limited thereto. For example, the semiconductor package 100 may include six semiconductor chips including four first semiconductor chips 110, the uppermost semiconductor chip 110U, and the second semiconductor chip 120 and include the third semiconductor chip 130, or the semiconductor package 100 may include eight semiconductor chips including six first semiconductor chips 110, the uppermost semiconductor chip 110U, and the second semiconductor chip 120 and include the third semiconductor chip 130.

The first semiconductor chip 110 may include a first semiconductor substrate 111 having a first active surface 111A and a first inactive surface 111B provided to the opposite side of the first active surface 111A, a first wiring structure formed on the first active surface 111A of the first semiconductor substrate 111, and a plurality of first through electrodes 112 connected to the first wiring structure and penetrating at least a portion of the first semiconductor chip 110. However, the uppermost semiconductor chip 110U on the top first semiconductor chip 110T may have no through electrodes.

The first semiconductor chip 110 may be disposed such that the first semiconductor substrate 111 has the first active surface 111A facing downward and the first inactive surface 111B facing upward. Therefore, unless separately described in the specification, the upper surface of the first semiconductor chip 110 indicates the first inactive surface 111B of the first semiconductor substrate 111, and the lower surface of the first semiconductor chip 110 indicates one surface facing the first active surface 111A. However, when a description is made with reference to the first semiconductor chip 110, the lower surface of the first semiconductor chip 110, which the first active surface 111A of the first semiconductor substrate 111 faces, may be referred to as the front surface of the first semiconductor chip 110, and the upper surface of the first semiconductor chip 110, which the first inactive surface 111B faces, may be referred to as the rear surface of the first semiconductor chip 110.

Similarly, the second semiconductor chip 120 may include a second semiconductor substrate 121 having a second active surface 121A and a second inactive surface 120B provided to the opposite side of the second active surface 121A, a second wiring structure formed on the second active surface 121A of the second semiconductor substrate 121, and a plurality of second through electrodes 122 connected to the second wiring structure and penetrating at least a portion of the second semiconductor chip 120. The second semiconductor chip 120 may be disposed such that the second semiconductor substrate 121 has the second active surface 121A facing downward and the second inactive surface 121B facing upward.

In addition, the third semiconductor chip 130 may include a third semiconductor substrate 131 having a third active surface 131A and a third inactive surface 131B provided to the opposite side of the third active surface 131A, a third wiring structure formed on the third active surface 131A of the third semiconductor substrate 131, and a plurality of third through electrodes 132 connected to the third wiring structure and penetrating at least a portion of the third semiconductor chip 130. The third semiconductor chip 130 may be disposed such that the third semiconductor substrate 131 has the third active surface 131A facing downward and the third inactive surface facing upward 131B.

The first semiconductor substrate 111, the second semiconductor substrate 121, and the third semiconductor substrate 131 may include a semiconductor material, e.g., silicon (Si). However, embodiments are not limited thereto, and for example, the first semiconductor substrate 111, the second semiconductor substrate 121, and the third semiconductor substrate 131 may include a semiconductor material, such as germanium (Ge). The first semiconductor substrate 111, the second semiconductor substrate 121, and the third semiconductor substrate 131 may include a conductive region, e.g., an impurity-doped well, on the first active surface 111A, the second active surface 121A, and the third active surface 131A, respectively. The first semiconductor substrate 111, the second semiconductor substrate 121, and the third semiconductor substrate 131 may have various device isolation structures, such as a shallow trench isolation (STI) structure.

Each of the first semiconductor substrate 111, the second semiconductor substrate 121, and the third semiconductor substrate 131 may include various types of a plurality of individual devices. The plurality of individual devices may include various microelectronic devices, e.g., a metal-oxide-semiconductor field effect transistor (MOSFET), such as a complementary metal-oxide-semiconductor (CMOS) transistor, a system large scale integration (LSI), a micro-electro-mechanical system (MEMS), an active device, a passive device, and the like. The plurality of individual devices may be electrically connected to the conductive regions of the first semiconductor substrate 111, the second semiconductor substrate 121, and the third semiconductor substrate 131. Each of the first active surface 111A, the second active surface 121A, and the third active surface 131A may further include a conductive wiring or a conductive plug electrically connecting the plurality of individual devices to the conductive region of each of the first semiconductor substrate 111, the second semiconductor substrate 121, and the third semiconductor substrate 131. In addition, each of the plurality of individual devices may be electrically isolated from other neighboring individual devices by an insulating layer.

At least one of the first semiconductor chip 110, the second semiconductor chip 120, and the third semiconductor chip 130 may be a memory semiconductor chip. According to one or more embodiments, the third semiconductor chip 130 may include a serial-parallel conversion circuit configured to parallelize a data signal received from a controller chip and transmit same to a memory chip and may be a buffer chip for control of the first semiconductor chip 110 and the second semiconductor chip 120. The third semiconductor chip 130 may also be referred to as an interface die, a base die, a logic die, a master die, or the like. According to one or more embodiments, each of the first semiconductor chip 110 and the second semiconductor chip 120 may be a memory chip including memory cells. A description of the uppermost semiconductor chip 110U may be substantially similar to a description of the first semiconductor chip 110.

For example, the semiconductor package 100 including the first semiconductor chip 110, the second semiconductor chip 120, and the third semiconductor chip 130 may be a high bandwidth memory (HBM), and the third semiconductor chip 130 may be referred to as an HBM controller die and the first semiconductor chip 110 and the second semiconductor chip 120 may be referred to as dynamic random access memory (DRAM) dies.

Each of a first through electrode 112, a second through electrode 122, and a third through electrode 132 may be formed by a through silicon via (TSV). Each of the first through electrode 112, the second through electrode 122, and the third through electrode 132 may include a conductive plug penetrating each of the first semiconductor substrate 111, the second semiconductor substrate 121, and the third semiconductor substrate 131 and a conductive barrier layer surrounding the conductive plug. A via insulating layer may be between the first through electrode 112 and the first semiconductor substrate 111, between the second through electrode 122 and the second semiconductor substrate 121, and between the third through electrode 132 and the third semiconductor substrate 131 to surround the sidewalls of the first through electrode 112, the second through electrode 122, and the third through electrode 132. The first through electrode 112, the second through electrode 122, and the third through electrode 132 may be formed by any one of a via-first structure, a via-middle structure, and a via-last structure.

A first upper connection pad 113A may be on the upper surface of the first semiconductor chip 110, and a first lower connection pad 113B may be on the lower surface of the first semiconductor chip 110. The first wiring structure on the first active surface 111A and the plurality of first through electrodes 112 may electrically connect the first upper connection pad 113A and the first lower connection pad 113B provided to the first semiconductor chip 110.

In the present disclosure, when it is described that a certain element is electrically connected to another element, it should be understood that the certain element may be connected to another element directly or via another conductive element in the middle. When it is described that a certain element is electrically connected to a semiconductor chip, it may be indicated that the certain element is electrically connected to integrated circuits of the semiconductor chip. When it is described that a certain element is connected to through vias and/or integrated circuits, it may be indicated that the certain element is electrically connected to at least one of the through vias and the integrated circuits.

A second upper connection pad 123A may be on the upper surface of the second semiconductor chip 120, and a second lower connection pad 123B may be on the lower surface of the second semiconductor chip 120. The second wiring structure on the second active surface and the plurality of second through electrodes 122 may electrically connect the second upper connection pad 123A and the second lower connection pad 123B provided to the second semiconductor chip 120.

Similarly, a third upper connection pad 133A may be on the upper surface of the third semiconductor chip 130, and a third lower connection pad 133B may be on the lower surface of the third semiconductor chip 130. The third wiring structure on the third active surface 131A and the plurality of third through electrodes 132 may electrically connect the third upper connection pad 133A and the third lower connection pad 133B provided to the third semiconductor chip 130. A third chip connection terminal 134 may be on the third lower connection pad 133B. Each of a first chip connection terminal 114, a second chip connection terminal 124, and the third chip connection terminal 134 may be a solder bump or a solder ball.

The first chip connection terminal 114 may be between one first semiconductor chip 110 and an adjacent first semiconductor chip 110. The first chip connection terminal 114 may be between the first lower connection pad 113B on the lower surface of one first semiconductor chip 110 and the first upper connection pad 113A on the upper surface of an adjacent first semiconductor chip 110. The first chip connection terminal 114 may electrically connect the first lower connection pad 113B on the lower surface of one first semiconductor chip 110 to the first upper connection pad 113A on the upper surface of an adjacent first semiconductor chip 110.

The uppermost semiconductor chip 110U may have a lower connection pad only on the lower surface of the uppermost semiconductor chip 110U, and the lower connection pad on the lower surface of the uppermost semiconductor chip 110U may be electrically connected to the first upper connection pad 113A on the upper surface of the top first semiconductor chip 110T by the first chip connection terminal 114.

The first chip connection terminal 114 may be between the first lower connection pad 113B of the bottom first semiconductor chip 110B and the second upper connection pad 123A on the upper surface of the second semiconductor chip 120, and the first lower connection pad 113B of the bottom first semiconductor chip 110B may be electrically connected to the second upper connection pad 123A on the upper surface of the second semiconductor chip 120 via the first chip connection terminal 114.

The second chip connection terminal 124 may be between the second lower connection pad 123B of the second semiconductor chip 120 and the third upper connection pad 133A on the upper surface of the third semiconductor chip 130, and the second lower connection pad 123B of the second semiconductor chip 120 may be electrically connected to the third upper connection pad 133A on the upper surface of the third semiconductor chip 130 via the second chip connection terminal 124.

In one or more embodiments, as shown in FIG. 1, the first through electrode 112 in the first semiconductor chip 110, the second through electrode 122 in the second semiconductor chip 120, and the third through electrode 132 in the third semiconductor chip 130 may be aligned in the vertical direction (Z direction). The aligned first through electrode 112, second through electrode 122, and third through electrode 132 may be electrically connected to each other.

An inter-chip molding material 115 may be between one first semiconductor chip 110 and an adjacent first semiconductor chip 110, between the uppermost semiconductor chip 110U and the top first semiconductor chip 110T, and between the bottom first semiconductor chip 110B and the second semiconductor chip 120. The inter-chip molding material 115 may include a non-conductive film (NCF) or a non-conductive paste (NCP). As shown in FIG. 1, all inter-chip molding materials 115 may be separated from one another. According to one or more other embodiments, one inter-chip molding material 115 may extend by protruding from a side surface of the first semiconductor chip 110 and be attached to or integrated with an adjacent inter-chip molding material 115 between different chips.

In one or more embodiments, instead of the inter-chip molding material 115 between semiconductor chips, unlike shown in FIG. 1, the first encapsulation material 210 may extend between the semiconductor chips by a molded underfill (MUF) scheme. According to one or more other embodiments, after bonding semiconductor chips, an underfill may be between the semiconductor chips by a capillary underfill (CUF) scheme.

The horizontal width of the first semiconductor chip 110 may be the same as the horizontal width of the uppermost semiconductor chip 110U. According to one or more other embodiments, the planar shape of the first semiconductor chip 110 may be the same as the planar shape of the uppermost semiconductor chip 110U in a horizontal direction (X and Y directions). The side surfaces of the plurality of first semiconductor chips 110 may be aligned in the vertical direction, and the side surfaces of the plurality of first semiconductor chips 110 and the side surfaces of the uppermost semiconductor chip 110U may also be aligned in the vertical direction. For example, the side surfaces of the plurality of first semiconductor chips 110 may be coplanar, and the side surfaces of the plurality of first semiconductor chips 110 and the side surfaces of the uppermost semiconductor chip 110U may also be coplanar.

A first thickness T1 that is the thickness of the first semiconductor chip 110 in the vertical direction may be less than or equal to the thickness of the uppermost semiconductor chip 110U in the vertical direction. For example, the first thickness T1 that is the thickness of the first semiconductor chip 110 in the vertical direction may be, for example, about 20 μm to about 60 μm. The thickness of the uppermost semiconductor chip 110U in the vertical direction may be, for example, about 30 μm to about 200 μm.

The horizontal width of the second semiconductor chip 120 may be greater than the horizontal width of the first semiconductor chip 110. According to one or more other embodiments, the planar shape of the outer periphery of the first semiconductor chip 110 may be included in the planar shape of the outer periphery of the second semiconductor chip 120. The planar shape of the second semiconductor chip 120 may be greater than the planar shape of the first semiconductor chip 110. The side surfaces of the first encapsulation material 210 to be described below and the side surfaces of the second semiconductor chip 120 may be aligned in the vertical direction. The side surfaces of the first encapsulation material 210 to be described below and the side surfaces of the second semiconductor chip 120 may be coplanar.

A second thickness T2 that is the thickness of the second semiconductor chip 120 in the vertical direction may be greater than or equal to the first thickness T1 that is the thickness of the first semiconductor chip 110 in the vertical direction. For example, the first thickness T1 that is the thickness of the first semiconductor chip 110 in the vertical direction may be, for example, about 20 μm to about 60 μm. The second thickness T2 that is the thickness of the second semiconductor chip 120 in the vertical direction may be, for example, about 20 μm to about 80 μm .

The horizontal width of the third semiconductor chip 130 may be greater than the horizontal width of the second semiconductor chip 120. According to one or more other embodiments, the planar shape of the outer periphery of the second semiconductor chip 120 may be included in the planar shape of the outer periphery of the third semiconductor chip 130. The planar shape of the third semiconductor chip 130 may be greater than the planar shape of the second semiconductor chip 120 and the planar shape of the first semiconductor chip 110. The side surfaces of the second encapsulation material 220 to be described below and the side surfaces of the third semiconductor chip 130 may be aligned in the vertical direction. The side surfaces of the second encapsulation material 220 to be described below and the side surfaces of the third semiconductor chip 130 may be coplanar.

A third thickness T3 that is the thickness of the third semiconductor chip 130 in the vertical direction may be greater than or equal to the second thickness T2 that is the thickness of the second semiconductor chip 120 in the vertical direction. For example, the second thickness T2 that is the thickness of the second semiconductor chip 120 in the vertical direction may be, for example, about 20 μm to about 80 μm . The third thickness T3 that is the thickness of the third semiconductor chip 130 in the vertical direction may be, for example, about 50 μm to about 100 μm .

However, embodiments are not limited to the aforementioned numerical illustrations of the first thickness T1 that is the thickness of the first semiconductor chip 110 in the vertical direction, the second thickness T2 that is the thickness of the second semiconductor chip 120 in the vertical direction, the third thickness T3 that is the thickness of the third semiconductor chip 130, and the thickness of the uppermost semiconductor chip 110U in the vertical direction.

The first encapsulation material 210 may be provided on and surround the uppermost semiconductor chip 110U and the plurality of first semiconductor chips 110 on the upper surface of the second semiconductor chip 120. The side surfaces of the first encapsulation material 210 and the side surfaces of the second semiconductor chip 120 may be aligned in the vertical direction. For example, the side surfaces of the first encapsulation material 210 and the side surfaces of the second semiconductor chip 120 may be coplanar. As described below in a semiconductor package manufacturing method, the first semiconductor chip 110 may be disposed on the second semiconductor chip 120 by a wafer on chip (CoW) process, and the first encapsulation material 210 may be provided on and surround the first semiconductor chip 110. Thereafter, both the first encapsulation material 210 and the second semiconductor chip 120 may be individualized and divided into individual elements that are separated from each other. Therefore, the side surfaces of the first encapsulation material 210 and the side surfaces of the second semiconductor chip 120 may be aligned in the vertical direction. For example, the side surfaces of the first encapsulation material 210 and the side surfaces of the second semiconductor chip 120 may be coplanar. The first encapsulation material 210 may include an epoxy mold compound (EMC). The first encapsulation material 210 may further include a filler.

The second encapsulation material 220 may be provided on and surround the side surfaces of the first encapsulation material 210 and the second semiconductor chip 120 on the upper surface of the third semiconductor chip 130. The side surfaces of the second encapsulation material 220 and the side surfaces of the third semiconductor chip 130 may be aligned in the vertical direction. For example, the side surfaces of the second encapsulation material 220 and the side surfaces of the third semiconductor chip 130 may be coplanar. A primary semiconductor package including the first semiconductor chip 110, the second semiconductor chip 120, and the first encapsulation material 210 is manufactured, then the third semiconductor chip 130, the primary semiconductor package, and the second encapsulation material 220 are simultaneously individualized (divided), and thus the side surfaces of the second encapsulation material 220 and the side surfaces of the third semiconductor chip 130 may be aligned in the vertical direction. For example, the side surfaces of the second encapsulation material 220 and the side surfaces of the third semiconductor chip 130 may be coplanar. The second encapsulation material 220 may include an EMC. The second encapsulation material 220 may further include a filler.

In the semiconductor package manufacturing method to be described below, the semiconductor package 100 may be manufactured by manufacturing the primary semiconductor package including the first semiconductor chip 110, the second semiconductor chip 120, and the first encapsulation material 210 and then disposing, by a foundry company or the like which is to perform a post-process, the primary semiconductor package on the third semiconductor chip 130 customized according to the demand of a consumer. Therefore, the semiconductor package 100 according to one or more embodiments may include the first encapsulation material 210 provided on and surrounding the first semiconductor chip 110 on the second semiconductor chip 120, and the second encapsulation material 220 provided on and surrounding the first encapsulation material 210 and the second semiconductor chip 120.

The primary semiconductor package including the first semiconductor chip 110, the second semiconductor chip 120, and the first encapsulation material 210 may be on the third semiconductor chip 130. In one or more embodiments, a first underfill layer 125 surrounding the second chip connection terminal 124 may be between the second semiconductor chip 120 and the third semiconductor chip 130.

In one or more embodiments, the first underfill layer 125 may fill the space between the second semiconductor chip 120 and the third semiconductor chip 130 and between second chip connection terminals 124. The first underfill layer 125 may be formed by, for example, a CUF process and include an epoxy resin.

The semiconductor package 100 according to one or more embodiments may be manufactured by manufacturing the primary semiconductor package including the first semiconductor chip 110, the second semiconductor chip 120, and the first encapsulation material 210 and then disposing, by a foundry company or the like which is to perform a post-process, the primary semiconductor package on the third semiconductor chip 130 customized according to the demand of a consumer. Therefore, because modular primary semiconductor packages may be mass-produced and customized memory semiconductor packages including the mass-produced primary semiconductor packages may be produced, a customized memory semiconductor package satisfying a particular requirement of a consumer may be more efficiently manufactured.

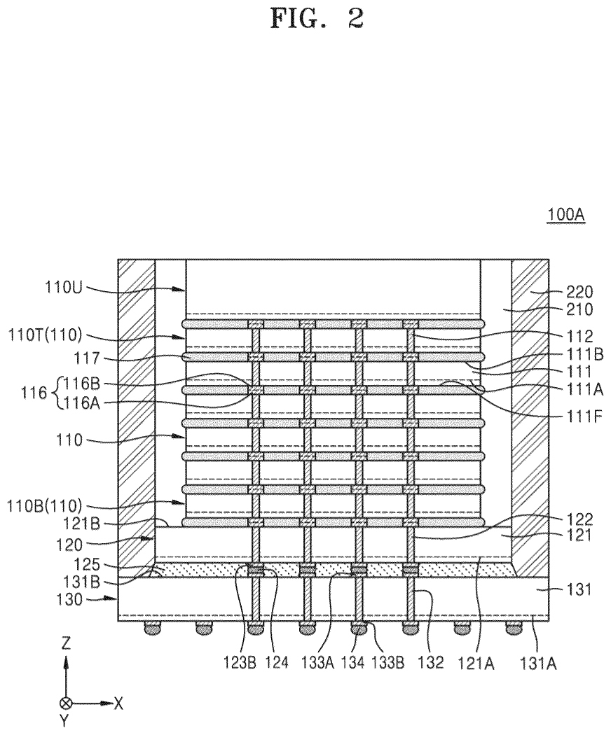

FIG. 2 is a cross-sectional view illustrating a semiconductor package 100A according to one or more embodiments. A description not separately made with reference to FIG. 2 may be substantially the same as the description made above.

Referring to FIG. 2, the semiconductor package 100A may include the first semiconductor chip 110, the uppermost semiconductor chip 110U, the second semiconductor chip 120, the third semiconductor chip 130, the first encapsulation material 210, and the second encapsulation material 220.

Two adjacent chips among the first semiconductor chip 110, the uppermost semiconductor chip 110U, and the second semiconductor chip 120 may be directly bonded. Direct bonding of two certain chips may include direct bonding of conductive elements of the two certain chips at positions facing each other and direct bonding of insulating elements of the two certain chips at positions facing each other. The direct bonding of the insulating elements may include chemical bonding between the insulating elements. Direct bonding of two certain chips may include hybrid bonding.

For example, a first lower pad 116B on the lower surface of one first semiconductor chip 110 may be directly on a first upper pad 116A on the upper surface of an adjacent first semiconductor chip 110, and the first lower pad 116B on the lower surface of the one first semiconductor chip 110 may be directly bonded with the first upper pad 116A on the upper surface of the adjacent first semiconductor chip 110. For example, a lower surface of the first lower pad 116B may contact an upper surface of the first upper pad 116A.

During a direct bonding process, metal atoms in the first lower pad 116B may diffuse into the first upper pad 116A and metal atoms in the first upper pad 116A may diffuse into the first lower pad 116B. Therefore, an interface between the first upper pad 116A and the first lower pad 116B may not be identified. Accordingly, the first lower pad 116B may be firmly bonded with the first upper pad 116A. In FIG. 2, a dotted line for distinguishing the first lower pad 116B from the first upper pad 116A may indicate a virtual interface. As described above, the first lower pad 116B and the first upper pad 116A integrated by a direct bonding process may be commonly referred to as a bonding pad 116. For example, the bonding pad 116 may be made of a material including copper (Cu).

Similarly, the first lower pad 116B on the lower surface of the bottom first semiconductor chip 110B may be directly bonded with a second upper pad on the upper surface of the second semiconductor chip 120. A description of the direct bonding may be substantially the same as described above.

A first lower insulating layer on the lower surface of one first semiconductor chip 110 may be in direct contact with a first upper insulating layer on the upper surface of an adjacent first semiconductor chip 110, and the first lower insulating layer on the lower surface of the one first semiconductor chip 110 may be connected to the first upper insulating layer on the upper surface of the adjacent first semiconductor chip 110 by direct bonding.

For example, chemical bonding may be provided between the first lower insulating layer on the lower surface of the one first semiconductor chip 110 and the first upper insulating layer on the upper surface of the adjacent first semiconductor chip 110. The chemical bonding may be covalent bonding. An interface between the first lower insulating layer and the first upper insulating layer may not be identified. In the present disclosure, the first lower insulating layer and the first upper insulating layer are shown without being distinguished from each other and may be commonly referred to as a first bonding insulating layer 117.

Because two adjacent semiconductor chips among the plurality of first semiconductor chips 110 and the second semiconductor chip 120 are connected to each other by direct bonding, bumps and/or solders may not be provided between the two adjacent semiconductor chips. Accordingly, the height of the semiconductor package 100A may decrease in the vertical direction, and the semiconductor package 100A may be miniaturized.

However, unlike two adjacent semiconductor chips among the plurality of first semiconductor chips 110 and the second semiconductor chip 120, which are connected to each other by direct bonding, the second semiconductor chip 120 may not be connected to the third semiconductor chip 130 by direct bonding. For example, as shown in FIG. 2, the second chip connection terminal 124 may be between the second lower connection pad 123B of the second semiconductor chip 120 and the third upper connection pad 133A on the upper surface of the third semiconductor chip 130, and the second lower connection pad 123B of the second semiconductor chip 120 may be electrically connected to the third upper connection pad 133A on the upper surface of the third semiconductor chip 130 via the second chip connection terminal 124. For example, the third chip connection terminal 134 may be a solder bump or a solder ball.

As described above, after manufacturing a primary semiconductor package including the first semiconductor chip 110, the second semiconductor chip 120, and the first encapsulation material 210, transporting the primary semiconductor package to a foundry company or the like which is to perform a post-process may be needed. According to one or more other embodiments, after manufacturing the primary semiconductor package including the first semiconductor chip 110, the second semiconductor chip 120, and the first encapsulation material 210, transporting the primary semiconductor package to a position where a post-process is to be performed may be needed. For example, after manufacturing the primary semiconductor package, manufacturing the semiconductor package 100A may not be a process to be consecutively performed in terms of time. Therefore, electrical connection between the second semiconductor chip 120 and the third semiconductor chip 130 may be achieved not by direct bonding but by the second chip connection terminal 124.

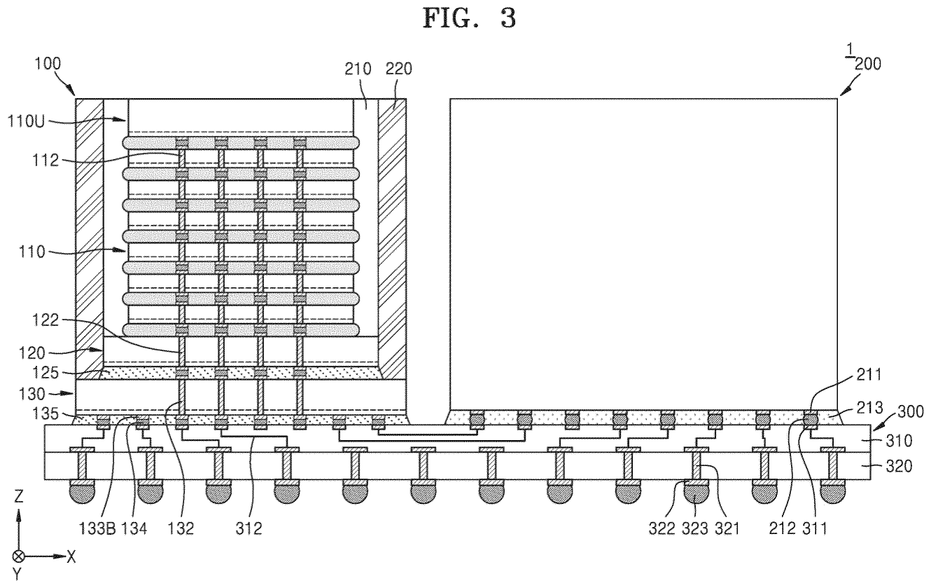

FIG. 3 is a cross-sectional view illustrating a semiconductor package 1 including an interposer according to one or more embodiments. A description not separately made with reference to FIG. 3 may be substantially the same as the description made above.

Referring to FIG. 3, the semiconductor package 1 including an interposer may include the semiconductor package 100 described with reference to FIG. 1, a first interposer 300, and a first semiconductor device 200. The semiconductor package 100 and the first semiconductor device 200 may be on the first interposer 300 by being separated from each other in a horizontal direction (X and/or Y direction).

The first semiconductor device 200 may be, for example, a system on chip, a central processing unit (CPU) chip, a graphics processing unit (GPU) chip, or an application processor (AP) chip. The first semiconductor device 200 may execute applications, which the semiconductor package 1 including an interposer supports. For example, the first semiconductor device 200 may execute dedicated operations by including at least one processor among a CPU, an AP, a GPU, a neural processing unit (NPU), a tensor processing unit (TPU), a vision processing unit (VPU), an image signal processor (ISP), and a digital signal processor (DSP).

The first interposer 300 may include a base layer 320. The base layer 320 may include a semiconductor material, glass, ceramic, or plastic. In one or more embodiments, the base layer 320 may include, for example, a Si wafer including Si, e.g., crystalline Si, polycrystalline Si, or amorphous Si. The base layer 320 may have a generally board shape.

The first interposer 300 may include a wiring structure 310 on the upper surface of the base layer 320. For example, the wiring structure 310 may include a back-end-of-line (BEOL) structure. The wiring structure 310 may include a wiring insulating layer covering the upper surface of the base layer 320 and a metal wiring pattern 312 sheathed (covered) by the wiring insulating layer. The metal wiring pattern 312 is schematically shown for the visibility of drawing.

A plurality of upper conductive pads 311 may be on the wiring structure 310. Some of the plurality of upper conductive pads 311 may be electrically connected to third lower connection pads 133B on the lower surface of the third semiconductor chip 130 by third chip connection terminals 134, respectively. Some of the remaining plurality of upper conductive pads 311 may be electrically connected to lower conductive pads 211 on the lower surface of the first semiconductor device 200 by lower conductive terminals 212, respectively.

The third semiconductor chip 130 included in the semiconductor package 100 may include a physical layer and a direct access area. The physical layer of the third semiconductor chip 130 may include interface circuits for communication with an external host device and may be electrically connected to the first semiconductor device 200 via the first interposer 300. The semiconductor package 100 may receive or transmit signals from or to the first semiconductor device 200 via the physical layer. Signals and/or data received via the physical layer of the third semiconductor chip 130 may be transmitted to the first semiconductor chip 110 and the second semiconductor chip 120 via the plurality of first to third through electrodes 112, 122, and 132.

The first semiconductor device 200 may include a physical layer and a memory controller. The physical layer of the first semiconductor device 200 may include input-output circuits configured to transmit and receive signals to and from the physical layer of the semiconductor package 100. The first semiconductor device 200 may provide various signals to the physical layer of the semiconductor package 100 via the physical layer of the first semiconductor device 200. The memory controller may control a general operation of the semiconductor package 100. The memory controller may transmit signals for controlling the semiconductor package 100 to the semiconductor package 100 via the metal wiring pattern 312 of the first interposer 300.

The first interposer 300 may include a low conductive pad 322 on the lower surface of the base layer 320. A through electrode 321 may extend by penetrating the base layer 320, and the low conductive pad 322 may be electrically connected to the metal wiring pattern 312 via the through electrode 321. A lower conductive terminal 323 may be on the low conductive pad 322.

The semiconductor package 100 may be on the first interposer 300, and a second underfill layer 135 may be between the semiconductor package 100 and the first interposer 300. The second underfill layer 135 may be provided on and surround the third chip connection terminal 134. Similarly, a third underfill layer 213 may be between the first semiconductor device 200 and the first interposer 300. The third underfill layer 213 may be provided on and surround the lower conductive terminals 212. The second underfill layer 135 and the third underfill layer 213 may be formed by a CUF process and include an epoxy resin.

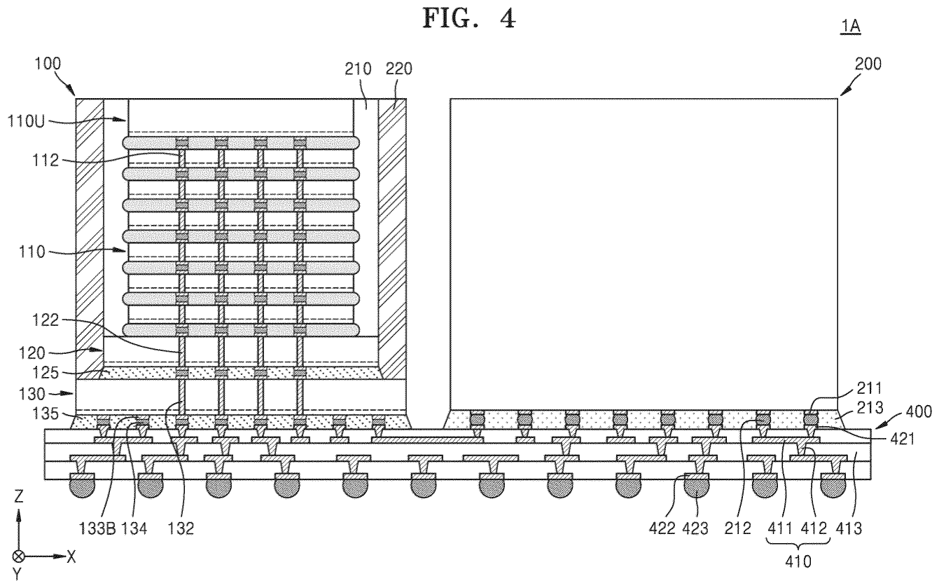

FIG. 4 is a cross-sectional view illustrating a semiconductor package 1A including an interposer according to one or more embodiments. A description not separately made with reference to FIG. 4 may be substantially the same as the description made above.

Referring to FIG. 4, the semiconductor package 1A including an interposer may include the semiconductor package 100 described with reference to FIG. 1, a second interposer 400, and the first semiconductor device 200. The semiconductor package 100 and the first semiconductor device 200 may be on the second interposer 400 by being separated from each other. The second interposer 400 may be referred to as a redistribution interposer.

The second interposer 400 may be formed by a redistribution process. The second interposer 400 may include a redistribution insulating layer 413 and a plurality of redistribution patterns 410. The redistribution insulating layer 413 may be provided on and surround the plurality of redistribution patterns 410. In one or more embodiments, the second interposer 400 may include a plurality of redistribution insulating layers 413 that are stacked. For example, the plurality of redistribution insulating layers 413 may include a first redistribution insulating layer, adjacent to the semiconductor package 100 and the first semiconductor device 200, and a second redistribution insulating layer beneath the first redistribution insulating layer. However, embodiments are not limited thereto and the plurality of redistribution insulating layers may include additional redistribution insulating layers.

The redistribution insulating layer 413 may be formed by a material layer including, for example, an organic compound. In one or more embodiments, at least one redistribution insulating layer 413 may be formed by a material layer including an organic polymer material. In one or more embodiments, the redistribution insulating layer 413 may be formed of photosensitive polyimide (PSPI). The redistribution insulating layer 413 may include a photo imageable dielectric. The redistribution insulating layer 413 may include, for example, a photosensitive polymer. The photosensitive polymer may include at least one of, for example, PSPI, polybenzoxazole, a phenol-based polymer, and q benzocyclobutene-based polymer.

The plurality of redistribution patterns 410 may include a plurality of redistribution line patterns 411 and a plurality of redistribution via patterns 412. The plurality of redistribution patterns 410 may include, for example, a metal, such as Cu, aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy of the metal, but is not limited thereto.

The plurality of redistribution line patterns 411 may be at least one surface of the upper surface and the lower surface of the redistribution insulating layer 413. The plurality of redistribution via patterns 412 may be connected to some of the plurality of redistribution line patterns 411 by penetrating the redistribution insulating layer 413. The plurality of redistribution via patterns 412 may have a tapered shape extending with a horizontal width gradually decreasing in the direction away from the semiconductor package 100 or the first semiconductor device 200.

In one or more embodiments, some of the plurality of redistribution line patterns 411 may be integrated with some of the plurality of redistribution via patterns 412. For example, a redistribution line pattern 411 and a redistribution via pattern 412 in contact with the lower surface of the redistribution line pattern 411 may be formed together and integrated.

In one or more embodiments, at least some of the top redistribution line patterns 411 among the plurality of redistribution line patterns 411 may be some of the plurality of upper conductive pads 311 (see FIG. 3) to which the lower conductive terminals 212 are attached. At least some of the bottom redistribution line patterns 411 among the plurality of redistribution line patterns 411 may be low conductive pads 322 to which lower conductive terminals 323 are attached.

The semiconductor package 100 may be electrically connected to the first semiconductor device 200 via the second interposer 400. For example, the physical layer of the semiconductor package 100 may receive or transmit signals from or to the first semiconductor device 200 via the second interposer 400. The memory controller of the first semiconductor device 200 may transmit signals for controlling the semiconductor package 100 to the semiconductor package 100 via the plurality of redistribution patterns 410 of the second interposer 400.

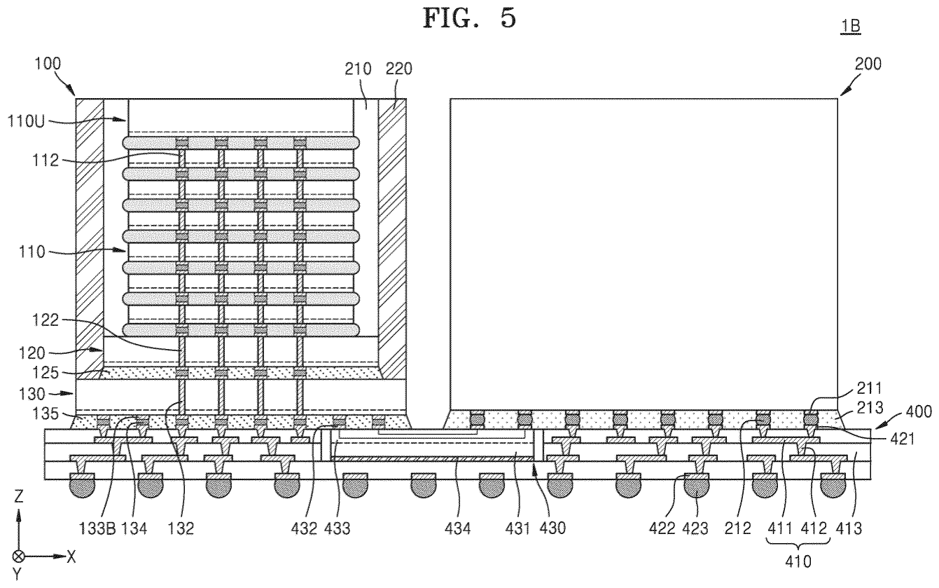

FIG. 5 is a cross-sectional view illustrating a semiconductor package 1B including an interposer according to one or more embodiments. A description not separately made with reference to FIG. 5 may be substantially the same as the description made above.

Referring to FIG. 5, the semiconductor package 1B including an interposer may include the semiconductor package 100 described with reference to FIG. 1, the second interposer 400, a bridge chip 430, and the first semiconductor device 200. The semiconductor package 100 and the first semiconductor device 200 may be on the second interposer 400 by being separated from each other. The second interposer 400 may be referred to as a redistribution interposer.

The bridge chip 430 may include a bridge chip substrate 431. The bridge chip 430 may include a Si wafer including Si, e.g., crystalline Si, polycrystalline Si, or amorphous Si.

The bridge chip 430 may be in a cavity formed in at least one redistribution insulating layer 413 of the second interposer 400. The cavity may indicate a groove formed in the at least one redistribution insulating layer 413 when the at least one redistribution insulating layer 413 is recessed. The bridge chip 430 may electrically connect the semiconductor package 100 to a plurality of semiconductor devices including the first semiconductor device 200. A wiring layer 433 may be provided adjacent to one surface of the bridge chip 430. The wiring layer 433 may include a wiring pattern, and the wiring pattern is schematically shown for the visibility of drawing.

A chip connection pad 432 is on the upper surface of the bridge chip 430 and connected to the third lower connection pad 133B by the third chip connection terminal 134. The chip connection pad 432 may be electrically connected to the third lower connection pad 133B via the third chip connection terminal 134. Similarly, the chip connection pad 432 may be electrically connected to a lower conductive pad 211 of the first semiconductor device 200 via a lower conductive terminal 212.

The bridge chip 430 may correspond to input/output (I/O) densities of the semiconductor package 100 and the plurality of semiconductor devices including the first semiconductor device 200, which are on the second interposer 400, and be provided for improved electrical signal characteristics among the plurality of semiconductor devices.

An adhesive layer 434 may be in the cavity to dispose the bridge chip 430 thereon. According to one or more embodiments, the adhesive layer 434 may be in the cavity to be provided on and surround not only one surface of the bridge chip 430 but also the side surfaces of the bridge chip 430.

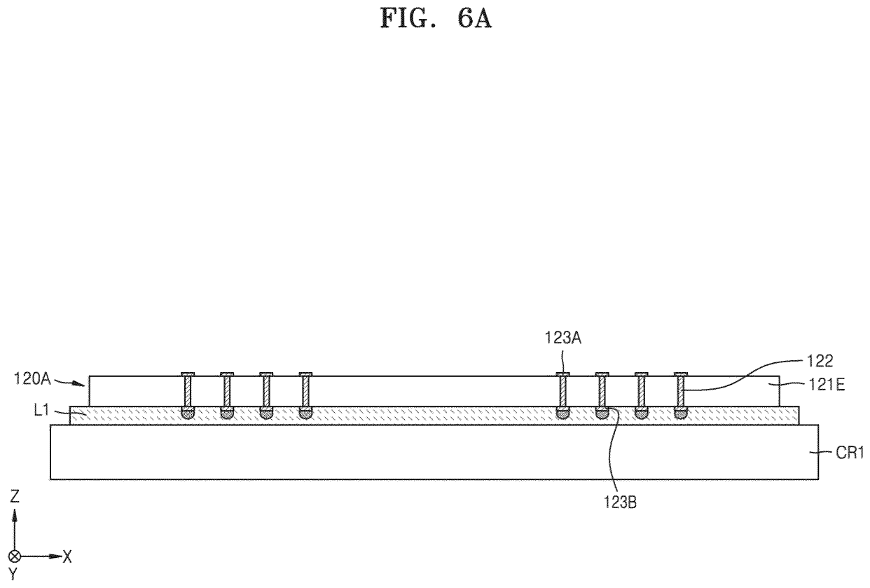

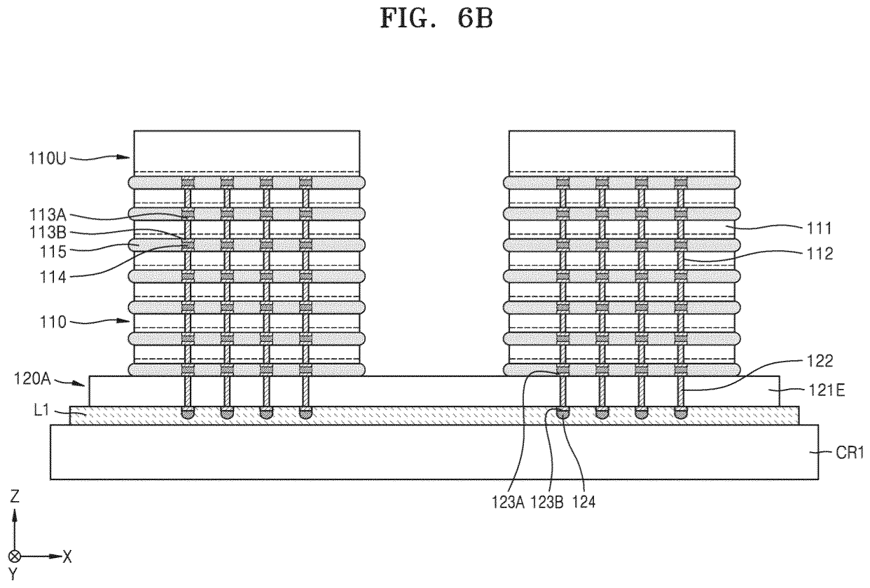

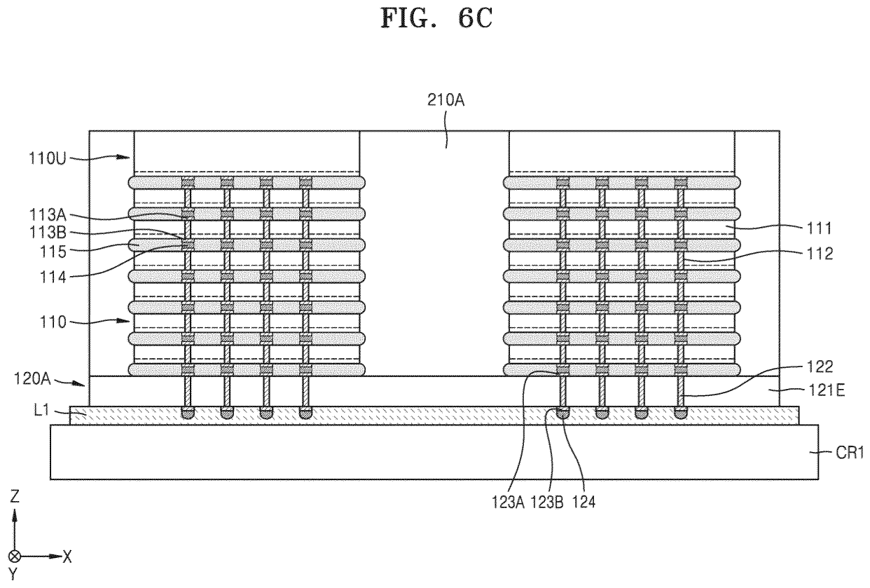

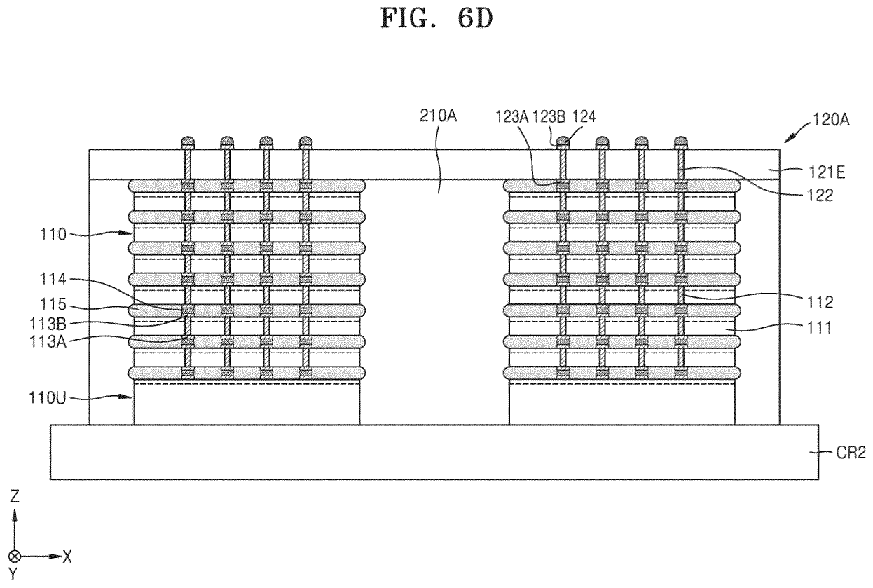

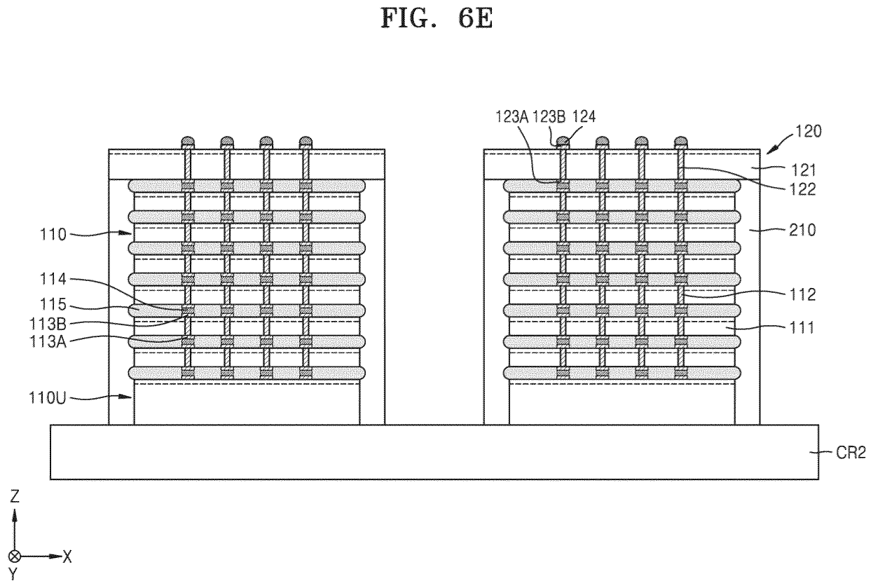

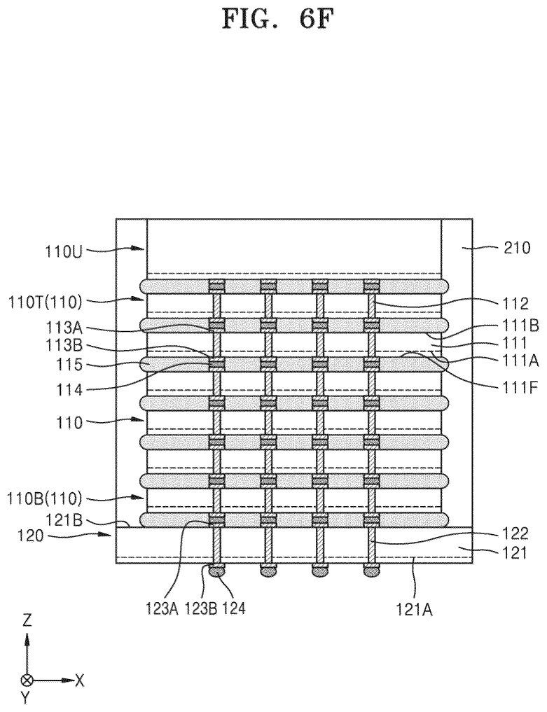

FIGS. 6A to 6F are cross-sectional views sequentially illustrating a method of manufacturing the semiconductor package 100, according to one or more embodiments. A description not separately made with reference to FIGS. 6A to 6F may be substantially the same as the description made above.

Referring to FIG. 6A, a second substrate 121E may be disposed on a first carrier CR1. The second substrate 121E may be a portion of a wafer on which a plurality of second semiconductor chips 120A before individualization are formed. The second substrate 121E may be attached to the first carrier CR1 by a first attachment layer L1 that is between the second substrate 121E and the first carrier CR1.

The second substrate 121E may be disposed on the first carrier CR1 such that the second lower connection pad 123B faces the first carrier CR1. The first attachment layer L1 may be provided on and cover a second connection terminal on the second lower connection pad 123B. A back-side process may be performed on the upper surface of the second substrate 121E to make the second substrate 121E thinner. The back-side process may include, for example, a grinding process or a chemical mechanical polishing process. Thereafter, the second upper connection pad 123A described above may be formed on the upper surface of the second substrate 121E.

Referring to 6B, at least one first semiconductor chip 110 may be mounted on the second substrate 121E. For example, one or more first semiconductor chips 110 may be mounted on the second semiconductor chip 120A on the second substrate 121E to correspond to the second semiconductor chip 120A. The first semiconductor chip 110 and the uppermost semiconductor chip 110U may be semiconductor chips manufactured on and individualized (divided) from a separate wafer.

The first chip connection terminal 114 may be between one first semiconductor chip 110 and an adjacent first semiconductor chip 110. The first chip connection terminal 114 may be between the first lower connection pad 113B on the lower surface of one first semiconductor chip 110 and the first upper connection pad 113A on the upper surface of an adjacent first semiconductor chip 110. The inter-chip molding material 115 may be between one first semiconductor chip 110 and an adjacent first semiconductor chip 110. Mounting the first semiconductor chip 110 and the uppermost semiconductor chip 110U on the second substrate 121E may be performed by, for example, a thermo-compression bonding process.

In one or more embodiments, for example, in a process of manufacturing the semiconductor package 100A of FIG. 2, mounting the first semiconductor chip 110 and the uppermost semiconductor chip 110U on the second substrate 121E may be performed by the direct bonding process described above.

Referring to FIG. 6C, a first encapsulation material 210A may be formed on the second substrate 121E to be provided on and cover the sidewalls of the first semiconductor chip 110 and the uppermost semiconductor chip 110U. The first encapsulation material 210A may be formed between a plurality of stacks on the second substrate 121E, each stack including the plurality of first semiconductor chips 110. The first encapsulation material 210A may be formed by a wafer level.

The first encapsulation material 210A may be formed to be provided on and cover, for example, the upper surface of the uppermost semiconductor chip 110U. The first encapsulation material 210A covering the upper surface of the uppermost semiconductor chip 110U may be removed by a grinding process or a chemical mechanical polishing process. Therefore, the upper surface of the first encapsulation material 210A may be coplanar with the upper surface of the uppermost semiconductor chip 110U. For example, the upper surface of the first encapsulation material 210A may be aligned with the upper surface of the uppermost semiconductor chip 110U in the horizontal direction.

Referring to FIG. 6D, the first carrier CR1 and the first attachment layer L1 may be removed, and one surface of the second substrate 121E may be exposed. A result of the process of FIG. 6C may be disposed on a second carrier CR2. An electrical die sorting (EDS) test may be performed on the result of the process of FIG. 6C, which is disposed on the second carrier CR2. Product quality may be pre-emptively distinguished through the EDS test, and a process after individualization, which is to be performed with reference to FIG. 6E, may be selectively performed on the products with higher quality.

Referring to FIGS. 6E and 6F, a result of the process of FIG. 6D may be individualized to form a plurality of primary semiconductor packages each including the first semiconductor chip 110, the second semiconductor chip 120, and the first encapsulation material 210 that are spaced apart from each other on the second carrier CR2. For example, individualization may be performed by sawing (cutting/dividing) the result of the process of FIG. 6D along a scribe lane region. Due to the individualization for forming the plurality of primary semiconductor packages, the sidewalls of the first encapsulation material 210 and the sidewalls of the second semiconductor chip 120 may be aligned in the vertical direction. For example, based on the individualization, the sidewalls of the first encapsulation material 210 and the sidewalls of the second semiconductor chip 120 may be coplanar.

After manufacturing the plurality of primary semiconductor packages, the plurality of primary semiconductor packages may be transported to perform a post-process thereon. For example, the plurality of primary semiconductor packages may be stored in a tape having pockets each being produced to meet a primary semiconductor package module, and the tape may be rolled around a reel, stored, and then transported. According to one or more other embodiments, the plurality of primary semiconductor packages may be loaded on a semiconductor package transport tray, then packaged, and transported to a place where a post-process is to be performed. The inventive concept is not limited to the description related to transportation of the plurality of primary semiconductor packages.

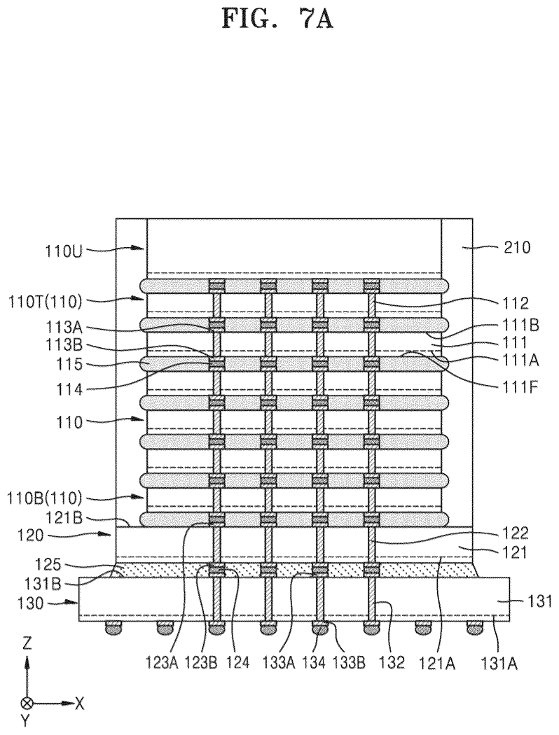

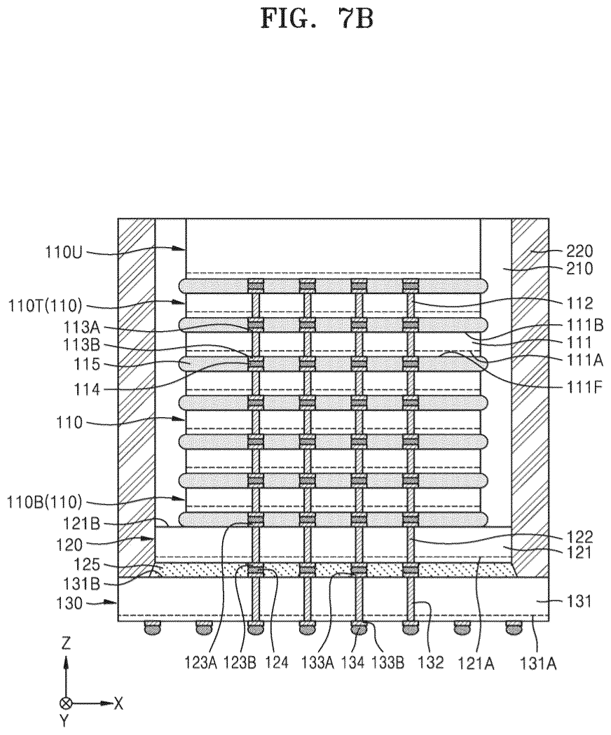

FIGS. 7A and 7B are cross-sectional views sequentially illustrating a method of manufacturing the semiconductor package 100, according to one or more embodiments. A description not separately made with reference to FIGS. 7A and 7B may be substantially the same as the description made above.

Referring to FIG. 7A, a primary semiconductor package may be mounted on the third semiconductor chip 130. For example, on a wafer having a plurality of third semiconductor chips 130, the primary semiconductor package may be mounted on the third semiconductor chip 130. For example, in a CoW process, the primary semiconductor package may be provided on a wafer having the plurality of third semiconductor chips 130.

When the primary semiconductor package is disposed on the third semiconductor chip 130, a thermo-compression bonding process may be performed. By the thermo-compression bonding process, the second lower connection pad 123B of the second semiconductor chip 120 may be connected to the third upper connection pad 133A on the upper surface of the third semiconductor chip 130 by the second chip connection terminal 124. Thereafter, the first underfill layer 125 provided on and surrounding the second chip connection terminal 124 may be between the second semiconductor chip 120 and the third semiconductor chip 130.

Referring to FIG. 7B, the second encapsulation material 220 may be formed on the third semiconductor chip 130 to be provided on and cover the primary semiconductor package. For example, on the wafer having the plurality of third semiconductor chips 130 each having the primary semiconductor package thereon, the second encapsulation material 220 may be formed to be on and surround the primary semiconductor package.

The second encapsulation material 220 provided on and covering the upper surface of the uppermost semiconductor chip 110U may be removed by a grinding process or a chemical mechanical polishing process. Therefore, the upper surface of the first encapsulation material 210 may be coplanar with the upper surface of the second encapsulation material 220 and the upper surface of the uppermost semiconductor chip 110U. For example, the upper surface of the first encapsulation material 210 may be aligned with the upper surface of the second encapsulation material 220 and the upper surface of the uppermost semiconductor chip 110U in the horizontal direction.

Thereafter, individualization for cutting the wafer including the second encapsulation material 220 and the third semiconductor chip 130 may be performed. In one or more embodiments, the individualization may be performed by sawing (cutting/dividing) the wafer including the second encapsulation material 220 and the third semiconductor chip 130, and thus, the side surfaces of the second encapsulation material 220 and the side surfaces of the third semiconductor chip 130 may be aligned in the vertical direction. By this sawing process, the semiconductor package 100 of FIG. 1 may be manufactured.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a plurality of first semiconductor chips respectively comprising a first semiconductor substrate and a plurality of first through electrodes penetrating the first semiconductor substrate;
a second semiconductor chip on the plurality of first semiconductor chips, the second semiconductor chip comprising a second semiconductor substrate and a plurality of second through electrodes penetrating the second semiconductor substrate;
a third semiconductor chip on the second semiconductor chip, the third semiconductor chip comprising a third semiconductor substrate and a plurality of third through electrodes penetrating the third semiconductor substrate; and
a first encapsulation material on the plurality of first semiconductor chips,
wherein a planar shape of the second semiconductor chip is greater than a planar shape of each first semiconductor chip of the plurality of first semiconductor chips, and a planar shape of the third semiconductor chip is greater than the planar shape of the second semiconductor chip.

2. The semiconductor package of claim 1, wherein side surfaces of the first encapsulation material and side surfaces of the second semiconductor chip are aligned in a vertical direction.

3. The semiconductor package of claim 1, further comprising a second encapsulation material on the third semiconductor chip, the first encapsulation material, and the second semiconductor chip.

4. The semiconductor package of claim 3, wherein side surfaces of the third semiconductor chip and side surfaces of the second encapsulation material are aligned in a vertical direction.

5. The semiconductor package of claim 3, wherein an upper surface of the first encapsulation material is aligned with an upper surface of the second encapsulation material in a horizontal direction.

6. The semiconductor package of claim 1, wherein at least some first through electrodes of the plurality of first through electrodes, at least some second through electrodes of the plurality of second through electrodes, and at least some third through electrodes of the plurality of third through electrodes are aligned with each other in a vertical direction.

7. The semiconductor package of claim 1, further comprising an uppermost semiconductor chip on the plurality of first semiconductor chips,
wherein the uppermost semiconductor chip comprises no through electrodes.

8. The semiconductor package of claim 1, wherein the plurality of first semiconductor chips and the second semiconductor chip comprise memory chips, and the third semiconductor chip comprises a buffer chip.

9. The semiconductor package of claim 1, wherein each first semiconductor chip of the plurality of first semiconductor chips has a first active area, the second semiconductor chip has a second active area, a third semiconductor chip has a third active area,
wherein the first active area is closer to a lower surface of each first semiconductor chip of the plurality of first semiconductor chips than an upper surface of each first semiconductor chip of the plurality of first semiconductor chips, the second active area is closer to a lower surface of the second semiconductor chip than an upper surface of the second semiconductor chip, and the third active area is closer to a lower surface of the third semiconductor chip than an upper surface of the third semiconductor chip.

10. The semiconductor package of claim 1, wherein a first chip connection pad is on each of an upper surface of each first semiconductor chip of the plurality of first semiconductor chips and a lower surface of each first semiconductor chip of the plurality of first semiconductor chips,
wherein a second chip connection pad is on each of an upper surface of the second semiconductor chip and a lower surface of the second semiconductor chip,
wherein a third chip connection pad is on each of an upper surface of the third semiconductor chip and a lower surface of the third semiconductor chip,
wherein a first chip connection terminal is between the first chip connection pad and the second chip connection pad, and a second chip connection terminal is between the second chip connection pad and the third chip connection pad.

11. The semiconductor package of claim 1, wherein one first semiconductor chip included in the plurality of first semiconductor chips is directly bonded with an adjacent first semiconductor chip, the second semiconductor chip is directly bonded with a bottommost first semiconductor chip among the plurality of first semiconductor chips, a second chip connection pad is on a lower surface of the second semiconductor chip, a third chip connection pad is on each of an upper surface of the third semiconductor chip and a lower surface of the third semiconductor chip, and a second chip connection terminal is between the second chip connection pad and the third chip connection pad.

12. The semiconductor package of claim 1, wherein a first thickness of each first semiconductor chip of the plurality of first semiconductor chips is less than or equal to a second thickness of the second semiconductor chip in a vertical direction, and the second thickness is less than or equal to a third thickness of the third semiconductor chip in the vertical direction.

13. A semiconductor package comprising:
a primary semiconductor package comprising a plurality of first semiconductor chips respectively comprising a first semiconductor substrate and a plurality of first through electrodes penetrating the first semiconductor substrate;
a second semiconductor chip on the plurality of first semiconductor chips, the second semiconductor chip comprising a second semiconductor substrate and a plurality of second through electrodes penetrating the second semiconductor substrate;
an uppermost semiconductor chip on the plurality of first semiconductor chips;
a first encapsulation material on the plurality of first semiconductor;
a third semiconductor chip on the primary semiconductor package, the third semiconductor chip comprising a third semiconductor substrate and a plurality of third through electrodes penetrating the third semiconductor substrate; and
a second encapsulation material on the third semiconductor chip and the primary semiconductor package,
wherein a planar shape of the second semiconductor chip is greater than a planar shape of each first semiconductor chip of the plurality of first semiconductor chips, a planar shape of the third semiconductor chip is greater than the planar shape of the second semiconductor chip, and
wherein side surfaces of the first encapsulation material and side surfaces of the second semiconductor chip are aligned in a vertical direction, side surfaces of the third semiconductor chip and side surfaces of the second encapsulation material are aligned in the vertical direction, and an upper surface of the first encapsulation material is aligned with an upper surface of the second encapsulation material in a horizontal direction.

14. The semiconductor package of claim 13, further comprising a first interposer on the third semiconductor chip,
wherein the first interposer comprises:
an interposer base layer;
an interposer through electrode penetrating the interposer base layer; and
a wiring structure on a first surface of the interposer base layer.

15. The semiconductor package of claim 13, further comprising a second interposer on the third semiconductor chip,
wherein the second interposer comprises:
a plurality of redistribution insulating layers; and
a redistribution pattern between the plurality of redistribution insulating layers.

16. The semiconductor package of claim 15, wherein the second interposer comprises a first surface and a second surface that is opposite to the first surface, the first surface faces the third semiconductor chip, the second interposer has a cavity that is a groove recessed inward from the first surface, a bridge chip is in the cavity, and the bridge chip is electrically connected to the third semiconductor chip.

17. A method of manufacturing a semiconductor package, the method comprising:
forming a plurality of second semiconductor chips on a first wafer;
stacking a plurality of first semiconductor chips on each second semiconductor chip of the plurality of second semiconductor chips on the first wafer;
forming a first encapsulation material on the plurality of first semiconductor chips on the first wafer;
dividing the first wafer, on which the plurality of first semiconductor chips are stacked, into a plurality of primary semiconductor packages that are spaced apart from each other;
mounting the primary semiconductor packages on a third semiconductor chip; and
forming a second encapsulation material on the primary semiconductor packages on the third semiconductor chip,
wherein each first semiconductor chip of the plurality of first semiconductor chips, the second semiconductor chips, and the third semiconductor chip comprises a plurality of first through electrodes, a plurality of second through electrodes, and a plurality of third through electrodes, respectively.

18. The method of claim 17, wherein the stacking of the plurality of first semiconductor chips comprises mounting the plurality of first semiconductor chips on the first wafer by a thermocompression bonding process, and the mounting of the primary semiconductor packages comprises mounting the primary semiconductor packages on the third semiconductor chip by thermocompression bonding.

19. The method of claim 17, wherein the stacking of the plurality of first semiconductor chips comprises mounting the plurality of first semiconductor chips on the first wafer by a direct bonding process.

20. The method of claim 19, wherein the mounting of the primary semiconductor package comprises mounting the primary semiconductor packages on the third semiconductor chip by thermocompression bonding.
